(19) United States
(12) Patent Application Publication
(10) Pub. No.: US 2010/0304045 A1
(43) Pub. Date: Dec. 2, 2010

(54) METHOD OF AND APPARATUS FOR TREATING OR COATING A SURFACE

(76) Inventor: Michael Bisges, Sinzing (DE)

Correspondence Address: KF ROSS PC, 5683 RIVERDALE AVENUE, SUITE 203 BOX 900, BRONX, NY, 10471-0900, US

(21) Appl. No.: 12/599,824

(22) PCT Filed: Jul. 17, 2008
(86) PCT No.: PCT/EP2008/005821

§ 371 Date: Nov. 12, 2009

(30) Foreign Application Priority Data
Sep. 11, 2007 (DE) 10 2007 043 291.9

(51) Int. Cl. C23C 16/452; H05H 1/24

(52) U.S. Cl. 427/569; 118/723 R

(57) ABSTRACT

The invention relates to a method for treating or coating surfaces by means of a plasma. A carrier gas is thus introduced into at least one physically separate reaction chamber and mixed with the generated plasma beam such that the carrier gas is activated or a particle beam is generated which impinges the surface of a workpiece for treatment or coating independently of the plasma stream.

The invention relates to a method of treating or coating surfaces using a plasma jet. The invention further relates to an apparatus that is suitable for carrying out the method.

In the prior art, a plasma jet denotes a plasma flow having a jet or beam shape and that is projected by a plasma generator onto a surface of a substrate or workpiece situated at a given spacing from the apparatus. In principle, the actual jet-shaped plasma may be generated in two ways: by a dielectrically impeded discharge or by an arc discharge.

A plasma-jet generator that operates by dielectrically impeded discharge, also referred to as atmospheric pressure glow discharge, is known from WO 2005/125286. In this apparatus, two electrodes are separated by an insulated tube acting as a dielectric barrier. In addition, a carrier gas is passed through the apparatus. In this manner a plasma jet is generated when alternating voltage is applied between the electrodes at the free end of the apparatus.

A plasma-jet generator that operates by direct arc discharge is known from EP 0,761,415 [U.S. Pat. No. 5,837,958]. In this apparatus a direct electric arc forms between two spaced electrodes, and a carrier gas is also passed through the apparatus.

For treating or coating surfaces, in all the known apparatuses an attempt is made to mix the generated plasma beam and an additional process gas, used for the treatment or coating, immediately before or just after the plasma jet emerges from the plasma head in order to avoid or at least reduce deposits on the adjacent walls or on the outlet nozzle of the apparatus itself. There are always the disadvantages of the parallel flow direction of the process gas and the plasma beam and the resulting poor activation. In addition, as a result of the plasma beam emerging from the nozzle head the surrounding air is radicalized, leading to termination processes in the process gas that is actually activated.

In the apparatus described in above-referenced WO 2005/125286, which operates by dielectrically impeded discharge, in addition to the plasma-forming carrier gas a process gas is fed in via a tube inside the inner electrode. Only after exiting the outlet nozzle of the apparatus does admixture of plasma and process gas occur, in the space between the substrate and the plasma head. A disadvantage is the previously mentioned insufficient activation of the process gas, since, as described, the plasma jet and the process gas flow essentially in parallel onto the substrate, resulting in inadequate activation of the process gas.

WO 1999/020809 describes a further plasma-jet generator, in this case the process gas being supplied immediately upstream of the outlet nozzle. In this manner the chemical reactions in the region of the electrodes are avoided. In this apparatus, a minimum contact volume is provided between the plasma jet and process gas in order to avoid deposits of the already activated process gas in the plasma head of the apparatus.

A further disadvantage of the known apparatuses is that the plasma jet, which reacts only partially with the process gas, impinges largely unhindered on the surface to be treated or coated. The secondary irradiation of the plasma in the UV range and the direct physical contact of the plasma with the surface results in undesired chemical and physical processes at that location. This may cause splitting of polymers and undesired incorporation of oxygen into the surface.

The object of the present invention is to provide a method of treating or coating a surface in which a plasma beam in the form of a plasma jet and at least one process gas are thoroughly mixed and the maximum possible energy transfer of plasma to the process gas can occur, so that an optimally activated mixture of carrier gas and process gas impinges on the corresponding surface. The aim is to prevent direct contact between the plasma jet and the surface. A further object of the invention is to provide the simplest possible apparatus that is suitable for carrying out such a method according to the invention.

The object is achieved by use of a method having the features of claim 1, and an apparatus having the features of equivalent claim 4. The subclaims concern particularly advantageous refinements of the invention with regard to the method or apparatus.

The invention is based on the general inventive concept of mixing a generated plasma flow in the form of a plasma jet and at least one process gas in a separate space from which ambient air is excluded. To this end, the process gas is introduced into a reaction chamber downstream from the exit nozzle of a known plasma jet, and the most complete mixture possible of the plasma jet and the process gas is achieved in this reaction chamber by suitable jet guidance and corresponding flow geometry. Only after this occurs is the process gas activated in this manner brought into contact, via an exit nozzle, with the surface of the workpiece in order to condition this surface or cut layers on same.

According to one particularly advantageous embodiment of the invention, the flow directions of the plasma jet on the one hand and of the process gas on the other hand are perpendicular or essentially perpendicular upon entering the reaction chamber. This results in particularly intensive mixing of the two media.

According to a further advantageous embodiment of the invention, the plasma jet is passed into the reaction chamber essentially parallel to the surface of the workpiece to be treated or coated, and the process gas is fed in essentially perpendicular to the surface. In this embodiment both components are optimally mixed without the plasma jet itself being able to pass through the reaction chamber. This allows the reaction chamber to be small.

According to a further advantageous embodiment of the invention, the reaction chamber is also provided with a cooling/heating system to enable control of the chemical and physical processes occurring during mixture of the plasma jet and process gas. It is possible, for example, to pass a liquid heat-exchange medium through passage in the outside walls of the reaction chamber. Temperature control may also be carried out using an electric heating system.

Finally, according to a further advantageous refinement of the invention it is also possible to provide a plurality of plasma jets in the reaction chamber in such a way that a plurality of plasma jets may be mixed with the process gas.

It is also possible to supply different process gases in succession, and to this end to provide a plurality of reaction chambers or a combined two- or multistage reaction chamber.

All of the embodiments of the invention have a number of advantages over the prior art:
First, the plasma energy is almost completely transferred into activation of the process gas.
Furthermore, the exclusion of atmospheric oxygen in the reaction chamber prevents undesired side reactions between the ambient air, plasma, and process gas. Only the activated process gas, and not the plasma jet itself, is brought into contact with the surface of the workpiece to be treated or coated.
The harmful influence of secondary UV radiation is avoided by preventing direct contact between the plasma and the workpiece surface. Prevention of this direct contact also avoids other effects the plasma could cause on the workpiece surface, such as a change in the surface tension, introduction of reactive oxygen groups into this surface, etc.

The invention is explained in greater detail below with reference to the drawings by way of example wherein:

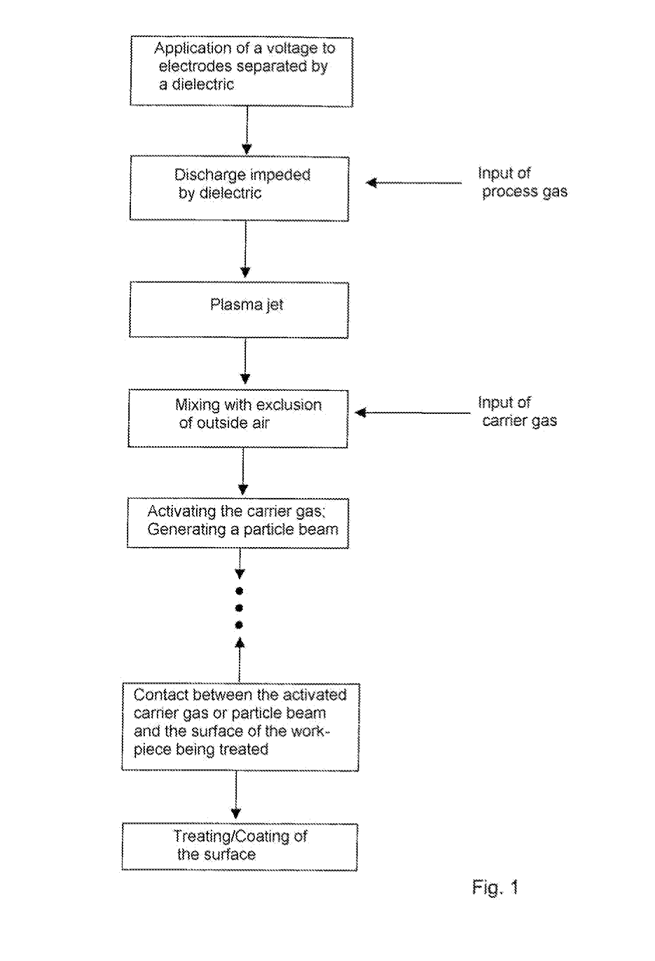

FIG. 1 shows a schematic flow diagram of a method according to the invention for treating or coating surfaces;

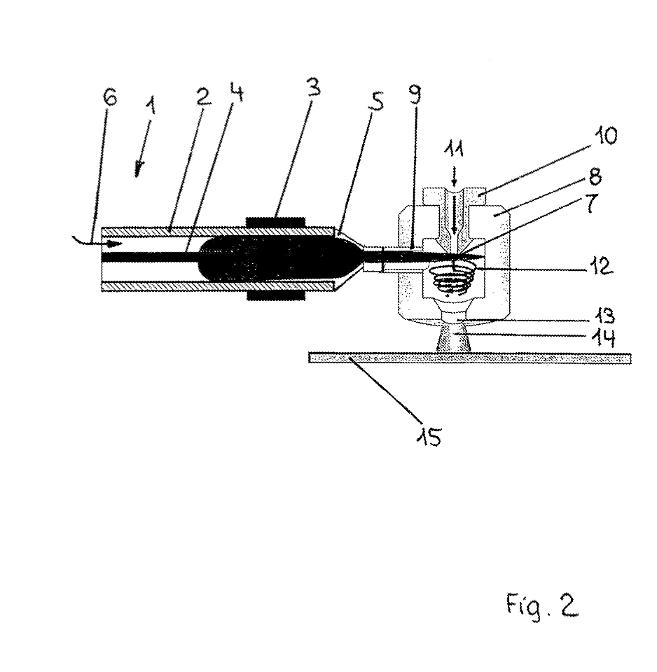

FIG. 2 shows a first apparatus according to the invention for treating or coating surfaces;

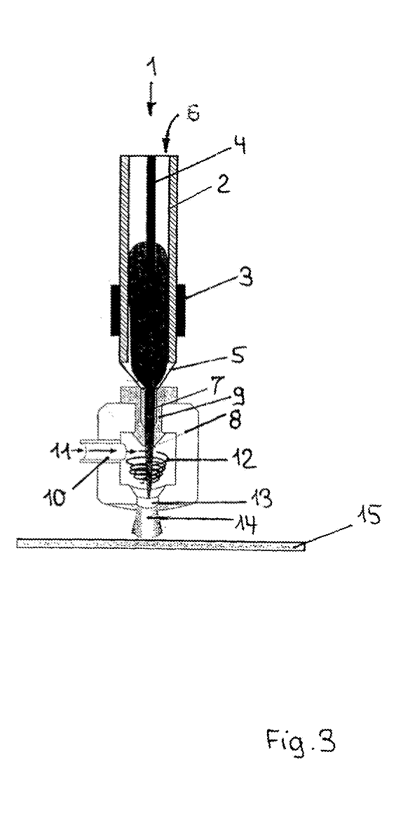

FIG. 3 shows a second apparatus of this type;

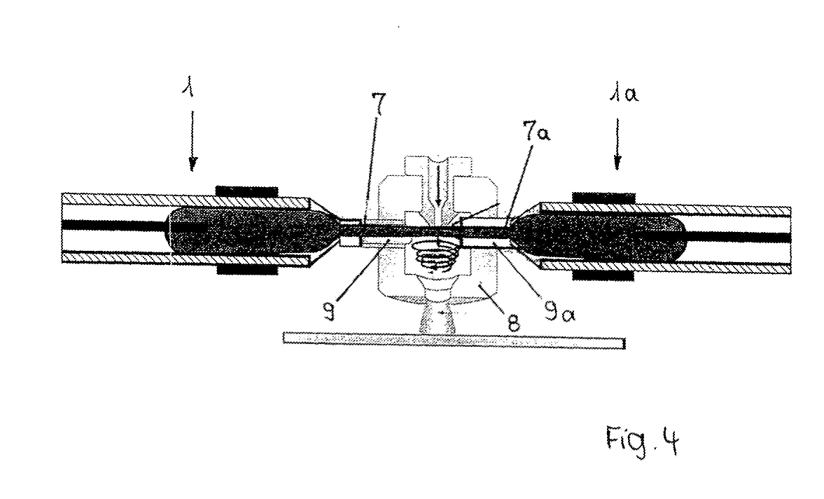

FIG. 4 shows a third apparatus of this type;

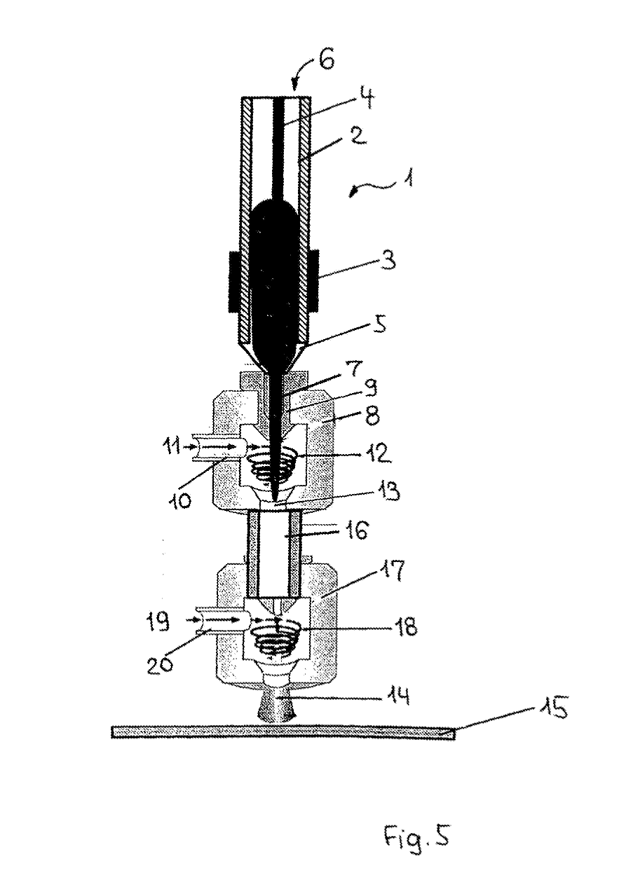

FIG. 5 shows a fourth apparatus of this type; and

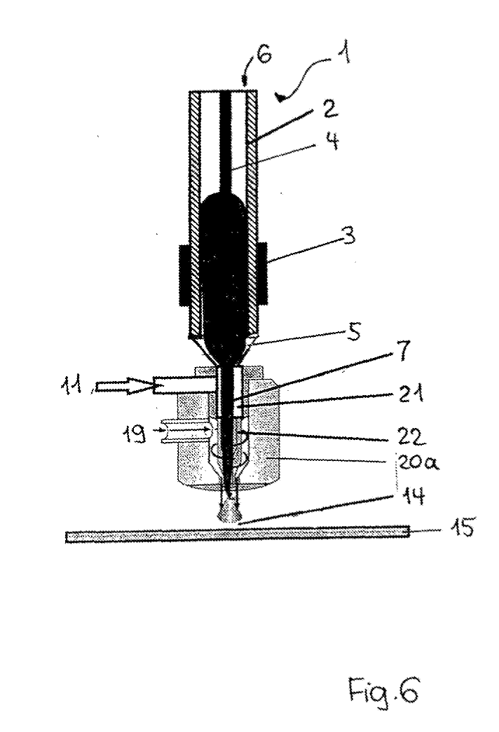

FIG. 6 shows a fifth apparatus of this type.

specific description First, the method schematically illustrated in FIG. 1 is explained in greater detail. In this example it is assumed that a plasma jet is generated by dielectrically impeded discharge. For this purpose a voltage is applied to electrodes separated from each other by a dielectric. In the apparatus according to WO 2005/125286 previously described, this is an insulated tube, the electrodes being provided concentrically inside and outside this insulated tube. A glow discharge is thus generated and process gas is fed to the apparatus to result in generation of a plasma jet that exits the apparatus. This plasma jet is then admixed with a separately supplied carrier gas, with exclusion of ambient air. The carrier gas is used for treating the surface of the workpiece, or contains the particles for subsequent coating of the surface of the workpiece. This admixture with exclusion of ambient air is completed in a reaction zone located outside the apparatus generating the plasma jet and in which a generated pressure with respect to the surroundings can prevail. Intensive mixing of the plasma jet on the one hand and the gas and particle stream contained in the carrier gas on the other hand takes place in this reaction zone. Thus, in this region the majority of the energy contained in the plasma is transferred to the gas and/or particle stream. In this regard it is practical to use suitable technical means to generate a superatmospheric pressure in the reaction zone, thus preventing ambient air from entering this region.

As a whole, as described, the supplied carrier gas is activated or a particle beam is generated in this reaction region.

It is also possible to repeat the last two method steps described, i.e. to provide a plurality of consecutive activation zones to which either the same carrier gas or different carrier gases may be supplied. Such a method having a plurality of activation zones is especially suited for achieving a particularly intensive activation of the carrier gas or to produce a mixture containing a plurality of activated gases.

In the discussion below, the carrier gas activated according to the above-described method steps or the particle beam is brought into contact with the workpiece surface to be treated, and the surface is treated or coated in this manner.

One characteristic of the described method according to the invention is that in the separate reaction region or regions the plasma beam transfers the majority of the plasma energy to the gas and/or particle stream, and, of particular importance, there is little or no direct contact of the plasma jet with the surface.

In the method according to the invention, it is also typical that, as a result of excluding ambient from the reaction zone, the previously mentioned undesired side reactions between ambient air, plasma, and process gas are avoided.

FIG. 2 shows a first apparatus according to the invention. The apparatus 1 for generating a plasma jet has a dielectric barrier 2, in the present case an insulated tube. An outer electrode 3 surrounds it, and an inner electrode 4 along in its center. At its free end the apparatus 1 is closed off by a plasma head 5. A process gas 6 is fed in along an axis in the direction indicated by the arrow, thereby generating a plasma jet 7 that exits through an opening in the plasma head 5. A closed reaction chamber 8 connected to the apparatus 1 has an inlet port 9 for the plasma jet 7. It is particularly advantageous to seal off this inlet port 9 from around the opening of the plasma head 5 in order to prevent entry of ambient air. The reaction chamber 8 also has an inlet port 10 through which a carrier gas 11 is blown axially into an interior 12 of the reaction chamber 8. The reaction chamber 8 also has an outlet port 13. The plasma jet 7 extends through the inlet port 9 and into the interior 12. There, the plasma jet 7 and carrier gas 11 mix intensively. The carrier gas 14 that is activated in this manner exits the reaction chamber 8 axially through the outlet port 13, impinges on a workpiece 15, and treats or coats its surface. In this design a reaction chamber 8 is provided with internal mixing, and the plasma jet 7 enters perpendicular to the jet of the activated carrier gas 14, resulting in particularly intensive mixing and energy exchange.

It is particularly advantageous when the inlet port 9 and outlet port 13 are situated at opposite ends of the reaction chamber 8, so that turbulence and/or deflection of the plasma jet 7 from a straight line occur as a result of an inlet port 10 provided on the side for the carrier gas 11 to be blown in.

FIG. 3 shows a further apparatus according to the invention in which, in contrast, the plasma jet 7 is injected into the reaction chamber 8 in the same direction that the active carrier gas 14 exits the reaction chamber.

FIG. 4 shows a further apparatus in which two identical apparatuses 1 and 1a for generating respective plasma jets 7 and 7a are provided on opposite sides. The reaction chamber 8 has two respective inlet ports 9 and 9a through which the two generated plasma jets 7 and 7a are passed into the interior 12.

FIG. 5 shows a further apparatus in which, connected to the outlet port 13 in the reaction chamber 8, a further reaction chamber 17 is provided that is joined to it by a conduit 16. Additional carrier gas 19 may be blown through a further inlet port 20 into an interior 18 of this further reaction chamber 17. The two carrier gases 11 and 19 may be identical or the same. It is possible, for example, to provide a plasma initiator as the first carrier gas 11 and to provide an aerosol, for example containing nanoparticles and/or binders, as the second carrier gas 19. Mixing the supplied medium with the corresponding supplied carrier gas takes place in each of the two reaction chambers 8 and 17.

FIG. 6 shows a further apparatus in which, as described for FIG. 5, a two-stage reaction chamber is provided. Whereas in the embodiment illustrated in FIG. 5 two identical reaction chambers 8 and 17 are a cascaded arrangement that may also comprise more than two reaction chambers, in the illustrated embodiment currently under discussion a combined reaction chamber 20a is provided that has a first interior space 21 and a second interior space 22. The supplied plasma jet 7 is mixed with the first carrier gas 11 in the first space 21. Further mixing of the activated medium exiting the first interior 21 with the additional carrier gas 19 takes place in the second space 22.

In one advantageous refinement of the invention, the reaction chamber 8 or the reaction chambers 8 and 17 may be heated or cooled by electricity or a liquid system. Condensation of the activated medium may be prevented by heating the respective reaction chamber. In this manner it is also possible by liquid temperature-control system for the liquid medium that is fed into the particular reaction chamber to be evaporated at that location instead of the carrier gas.

By correspondingly forming the outlet port in the apparatus facing the workpiece surface to be treated or coated in as a nozzle it is possible to produce a straight jet of the activated medium on the workpiece surface; likewise, it is possible within the scope of the invention to produce a fan-shaped or tapered jet, for example, by a suitable nozzle design.

It is also possible to adjust or close all or individual inlet and/or outlet ports in the apparatus via a nozzle system, an adjustable diaphragm, or other control possibilities known as such. In this manner the residence time of the plasma, gas, and/or particle streams in the respective reaction chamber may be set and changed by a simple adjustment of the cross section of the respective inlet and/or outlet port.

The apparatus according to the invention may particularly advantageously be composed of two separate modules. The Plasmabrush® apparatus manufactured and marketed by the present applicant, in which the plasma jet is generated by a dielectrically impeded discharge, may be advantageously used as the first module for generating a plasma jet. A second module may include one or more reaction chambers having the respective inlet and outlet ports. It is particularly advantageous to adapt an inlet port 9 in such a way that it has a modular design that directly corresponds to the plasma head 5 of the Plasmabrush® apparatus, thus allowing the plasma head 5 to be directly and sealingly mounted on the inlet port 9.

1-10. (canceled)

11. A method of treating or coating a surface, the method comprising the steps of:
creating a plasma jet by discharging electricity between two electrodes in the presence of a process gas;
feeding the plasma jet in a predetermined jet direction into a generally closed reaction chamber;
preventing oxygen-containing ambient air from entering the chamber while feeding a carrier gas into the chamber through an inlet port in a direction transverse to the jet direction;
swirling together and thoroughly mixing the plasma jet with the carrier gas in the chamber to activate the carrier gas or form a particle beam;
flowing the carrier gas or particle beam out of the chamber through an outlet port in a direction transverse to the jet direction while confining the plasma jet in the chamber; and
impinging the carrier gas or particle beam outside the chamber on the surface to be treated or coated.

12. The method defined in claim 11 wherein the activated carrier gas or particle beam is flowed out through the outlet port in a direction parallel to the direction in which the carrier gas is flowed into the chamber through the inlet port.

13. The method defined in claim 11, further comprising the step of
separating the electrodes with a dielectric for barrier-discharge formation of the plasma jet.

14. The method defined in claim 11 wherein a plurality of independent but parallel plasma jets are formed in the chamber.

15. The method defined in claim 14 wherein each of the plasma jets is mixed with the same carrier gas.

16. The method defined in claim 14 wherein the plasma jets are mixed with different carrier gases.

17. An apparatus for treating or coating a surface, the apparatus comprising:
a closed reaction chamber having a plasma-jet inlet port, a separate carrier-gas inlet port, and an outlet port, the carrier-gas inlet port and the outlet port opening into the chamber toward each other along a common axis of the chamber, the plasma-jet inlet port opening into the chamber transversely of the axis, the chamber being closed across from the plasma-jet inlet port;
a generator having two electrodes and a supply of process gas for forming a plasma jet and feeding it through the plasma-jet inlet port into the chamber transversely of the axis; and
means for
feeding a carrier gas into the chamber through the carrier-gas inlet port parallel to the axis and thereby swirling together and thoroughly mixing the plasma jet with the carrier gas to activate the carrier gas or form a particle beam,
flowing the carrier gas or particle beam out of the chamber through the outlet port in a direction parallel to the axis while confining the plasma jet in the chamber, and
impinging the carrier gas or particle beam outside the chamber on the surface to be treated or coated.

18. The apparatus defined in claim 17 wherein there are a plurality of the reaction chambers cascaded together with the outlet of all but the furthest downstream chamber connected to the carrier-gas inlet of the immediately downstream chamber.

19. The apparatus defined in claim 17 wherein the axes of all of the chambers are substantially coaxial.

20. The apparatus defined in claim 17, further comprising
controlling the temperature of the reaction chamber.

21. The apparatus defined in claim 17, further comprising
means for controlling the flow cross section of at least one of the ports.
